(19) United States
(12) Patent Application Publication
(10) Pub. No.: US 2015/0130441 A1
(43) Pub. Date: May 14, 2015

(54) DETECTION DEVICE AND METHOD FOR ELECTRONIC DEVICE

(71) Applicants: Fu Tai Hua Industry (Shenzhen) Co., Ltd., Shenzhen (CN); HON HAI PRECISION INDUSTRY CO., LTD., New Taipei (TW)

(72) Inventor: ZHAO-BO FENG, Shenzhen (CN)

(21) Appl. No.: 14/541,160

(22) Filed: Nov. 14, 2014

(30) Foreign Application Priority Data
Nov. 14, 2013 (CN) 201310564620.3

(51) Int. Cl. G01R 19/165; G01R 19/22; G01R 19/00

(52) U.S. Cl. CPC G01R 19/165; G01R 19/0084; G01R 19/22
USPC 324/76.11

(57) ABSTRACT

A detection method for an electronic device having a chip is disclosed. The method includes: obtaining, at a detection device, a voltage of at least one signal pin of a chip coupled to the detection device; converting, at the detection device, the obtained voltage to one or more digital voltage signals; and determining, at the detection device, if the one or more digital voltage signals are in a predetermined voltage range in which the chip is correctly operational.

### FIELD

The subject matter herein generally relates to a detection method and device for electronic device.

### BACKGROUND

An electronic device generally includes at least one pluggable chip which is coupled to a main board by signal pins. If the signal pins are wrongly connected, the chip can be not operational or even be damaged. So, there is a need to develop a method to detect whether the signal pins of the electronic device are correctly coupled.

### BRIEF DESCRIPTION OF THE DRAWINGS

Implementations of the present technology will now be described, by way of example only, with reference to the attached figures.

FIG. 1 is a diagrammatic view of a first exemplary embodiment of a detection device.

FIG. 2 is a diagrammatic view of a partial equivalent circuit of the detection device in FIG. 1.

FIG. 3 is a flowchart of a first exemplary embodiment of a detection method.

FIG. 4 is a diagrammatic view of a second exemplary embodiment of a detection device.

FIG. 5 is a diagrammatic view of a partial equivalent circuit of the detection device in FIG. 1.

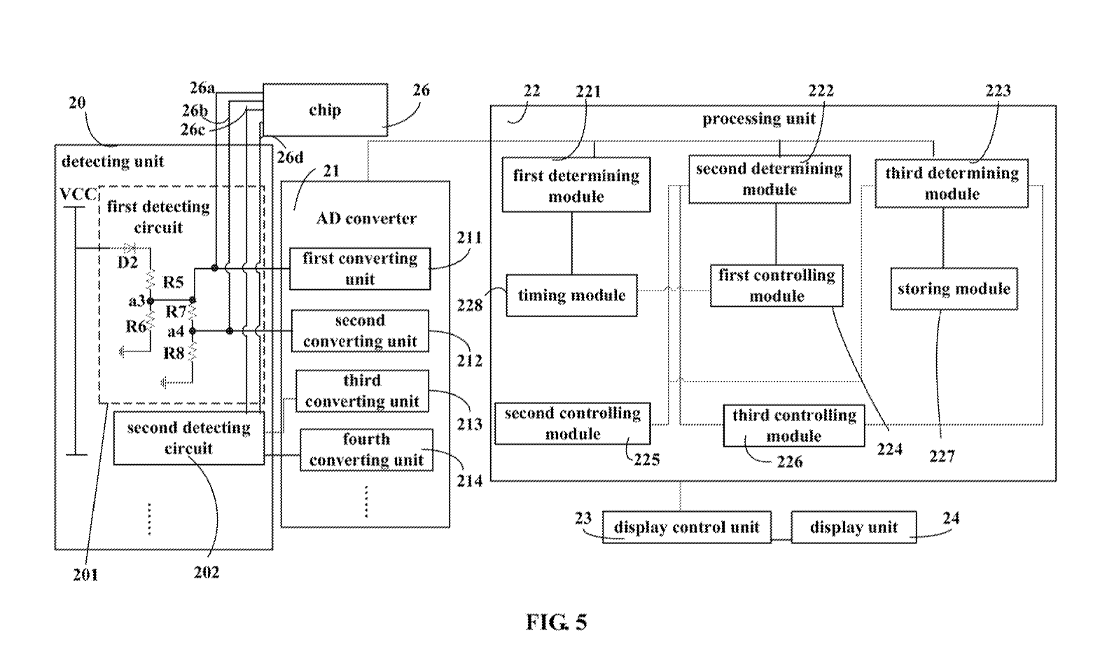

FIG. 6 is a flowchart of a second exemplary embodiment of a detection method.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “comprising,” when utilized, means “including, but not necessarily limited to”; it specifically indicates open-ended inclusion or membership in the so-described combination, group, series and the like.

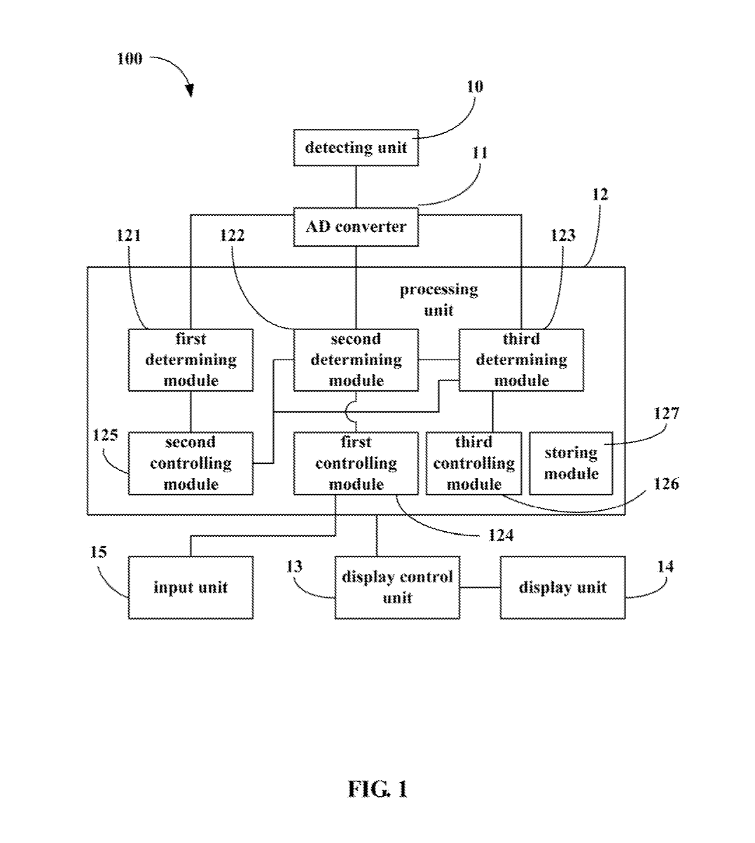

FIG. 1 illustrates a diagrammatic view of a first exemplary embodiment of a detection device 100. In the exemplary embodiment, the detection device 100 can be configured to detect whether signal pins of an electronic device are correctly coupled. The detection device 100 can be a microprocessor, a field-programmable gate array (FPGA), or a complicated programmable logic device (CPLD). The detection device 100 can include a detecting unit 10, an analog-digital (AD) converter 11, a processing unit 12, a display control unit 13, a display unit 14 and an input unit 15 coupled in turn.

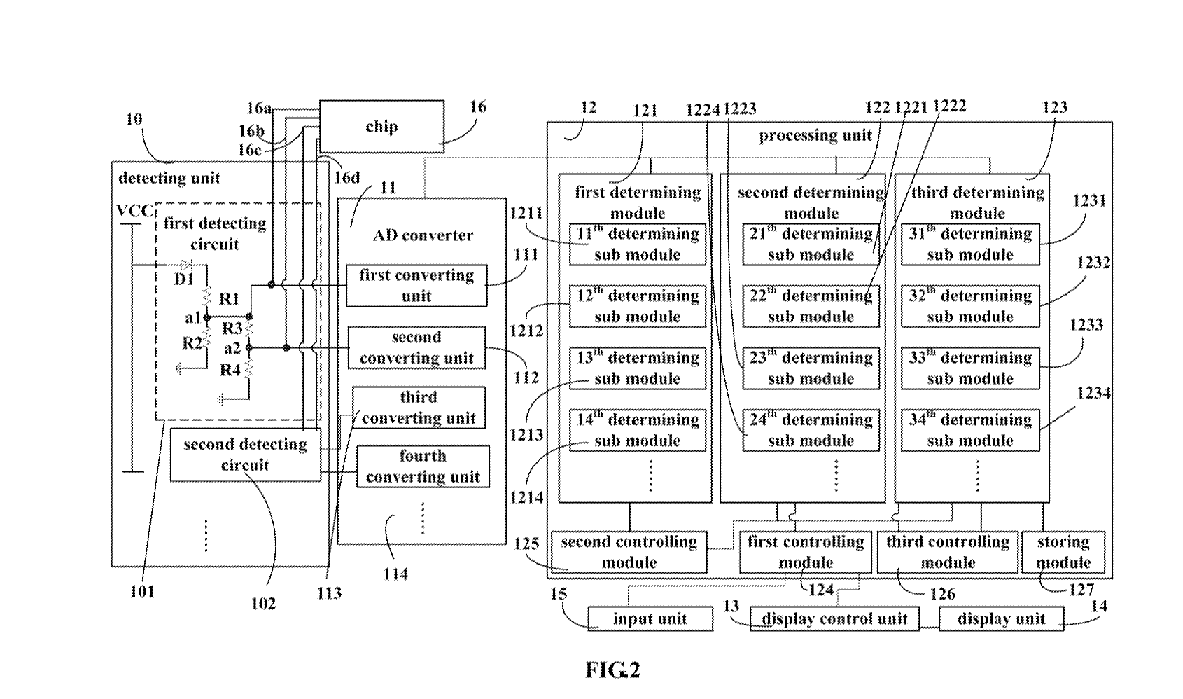

Referring to FIG. 2, the detecting unit 10 can be configured to detect voltage of signal pins of a chip 16. The voltage of signal pins of the chip 16 can be output from the detecting unit 10 to the AD converter 11. In the exemplary embodiment, the chip 16 can include four signal pins 16a, 16b, 16c and 16d. The signal pins 16a˜16d of the chip 16 can be configured to transmit data signal or power signal. The detecting unit 10 can include a plurality of detecting circuits, for example, a first detecting circuit 101, a second detecting circuit 102, being coupled to signal pins 16a˜16d of the chip 16 respectively. The plurality of detecting circuits can be in a same circuit structure. One end of the first detecting circuit 101 can be coupled to VCC, and the other end of the first detecting circuit 101 can be coupled to AD converter 11. The first detecting circuit 101 can include a diode D1 having an anode coupled to VCC and a cathode coupled to the ground via resistive element, for example, R1 and R2. The AD converter 11 can be coupled to a first connection point a1 between the two resistive elements R1 and R2. The first connection point a1 can be coupled to the ground via resistive elements R3 and R4. A second connection point a2 between the resistive elements R3 and R4 can be coupled to the AD converter 11. The first and second connection points a1 and a2 can be coupled to signal pins 16a, 16b respectively.

The AD converter 11 can be configured to receive voltage of signal pins 16a˜16d from the detecting unit 10 and then convert the voltage from analog signals to digital signals. In the exemplary embodiment, the AD converter 11 can include a plurality of converter unit coupled to the signal pins 16a˜16d respectively. In detail, a first converter unit 111 can be coupled to the first connection point a1 and the processing unit 12, and a second converter unit 112 can be coupled to the second connection point a2 and the processing unit 12. Similar to the first and converter units 111, 112, a third and a fourth converter units 113, 114 can be coupled between the second detecting circuit 102 and the processing unit 12.

The processing unit 12 can be a central processing unit (CPU), a microprocessor, or other data processor chip that performs functions of the detection device 100. The processing unit can include a first determining module 121, a second determining module 122, a third determining module 123, a first controlling module 124, a second controlling module 125, a third controlling module 126 and a storing module 127. The first determining module 121 can be configured to determine whether the voltage of the signal pins 16a˜16d is zero potential before the chip 16 is powered on. The first controlling module 124 can be configured to activate the second determining module 122 after the chip is powered on. The second controlling module can be configured to activate the second determining module 122 if the signal pins are proved to be zero potential before the chip is powered on. The second determining module 122 can be configured to determine whether the voltage of the signal pins 16a˜16d is low potential. The third controlling module 125 can be configured to activate the third determining module 123 if the voltage of the signal pins 16a˜16d is within a predetermined range in which the chip 16 is correctly operational. The predetermined range can be stored in the storing module 127.

The display control unit 13 can be configured to control the display unit 14 to display a user interface (UI). The UI can be configured to show a profile of signal pins 16a˜16d. The display unit 14 can be a light emitting diode (LED) screen. The input unit 15 can be a keyboard or a touch screen or other form input device.

The first determining module 121 can include a plurality of first determining sub modules, for example, a 11^{th} determining sub module 1211, a 12^{th} determining sub module 1212, a 13^{th} determining sub module 1213, and a 14^{th} determining sub module 1214. These first determining sub modules can be one-to-one correspond to the plurality of the converting units 111˜114. The first determining modules 1211˜1212 can be coupled to the converting units 111˜114 respectively. The first determining modules 1211˜1212 can be configured to determine whether voltage of signal pins 16a˜16d are zero potential before the chip 16 is powered on. If the voltage of the signal pins 16a˜16d are zero potential before the chip 16 is powered on, the signal pins 16a˜16d can be proved to be wrongly coupled to the ground.

The display control module 13 can be configured to control the display module 14 display information of the signal pins wrongly coupled to the ground. In the exemplary embodiment, the information of the signal pins wrongly coupled to the ground can be highlighted on the display module 14. In at least one exemplary embodiment, the detecting device 100 can include a warning unit, for example, a speaker, or a LED, configured to issue a warning message in a form of voice or light.

The input unit 15 can be configured to receive user input to active some predefined action, for example, to power on the chip 16. In the exemplary embodiment, the input unit 15 can be a touch screen. If the user input is powering on the chip 16, the first controlling module 124 can be configured to transmit a first command to the second determining module 122. The second controlling module 125 can be configured to transmit a second command to the second determining module 122 based on the determining result of the first determining module 121. In detail, if the determining result of the first determining module 121 is that the signal pins 16a˜16d are wrongly coupled to the ground, the second command can be deactivating the second determining module 122, otherwise, the second command can be activating the second determining module 122. If the second determining module 122 receives the first command and the second command that representing activating the second determining module 122, the second determining module 122 can be activated.

The second determining module 122 can include a plurality of second determining sub modules, for example, a 21^{th} determining sub module 1221, a 22^{th} determining sub module 1222, a 23^{th} determining sub module 1223, and a 24^{th} determining sub module 1224. These second determining sub modules can be one-to-one correspond to the plurality of the converting units 111˜114. The second determining modules 1221˜1224 can be coupled to the converting units 111˜114 respectively. The second determining modules 1221˜1224 can be configured to determine whether voltage of signal pins 16a˜16d are low potential after the chip 16 is powered on. If the voltage of the signal pins 16a˜16d are zero potential after the chip 16 is powered on, the signal pins 16a˜16d can be proved to be wrongly coupled in an open circuit.

The third controlling module 126 can be configured to transmit a third command to the third determining module 123 based on the determining result of the second determining module 122. In detail, if the determining result of the second determining module 122 is that the signal pins 16a˜16d are wrongly coupled in an open circuit, the third command can be deactivating the third determining module 123, otherwise, the third command can be activating the third determining module 123. If the signal pins 16a˜16d are proved to be wrongly coupled in an open circuit, the display control nit 13 can be configured to control the display module 14 to display information of the signal pins that wrongly coupled in an open circuit. In the exemplary embodiment, a warning unit, for example, a speaker, or a LED can be configured to issue a warning message representing the signal pins are wrongly coupled in an open circuit.

The third determining module 123 can include a plurality of third determining sub modules, for example, a 31^{th} determining sub module 1231, a 32^{th} determining sub module 1232, a 33^{th} determining sub module 1233, and a 34^{th} determining sub module 1234. These third determining sub modules 1231˜1234 can be one-to-one correspond to the plurality of the converting units 111˜114. The third determining modules 1231˜1234 can be coupled to the converting units 111˜114 respectively. The third determining modules 1231˜1234 can be configured to determine whether voltage of signal pins 16a˜16d are in a predetermined range. If the voltage of the signal pins 16a˜16d are in a predetermined range, the signal pins 16a˜16d can be proved to be correctly coupled. The predetermined range can be the voltage range in which the chip is correctly operational. The predetermined range can be stored in the storing module 127.

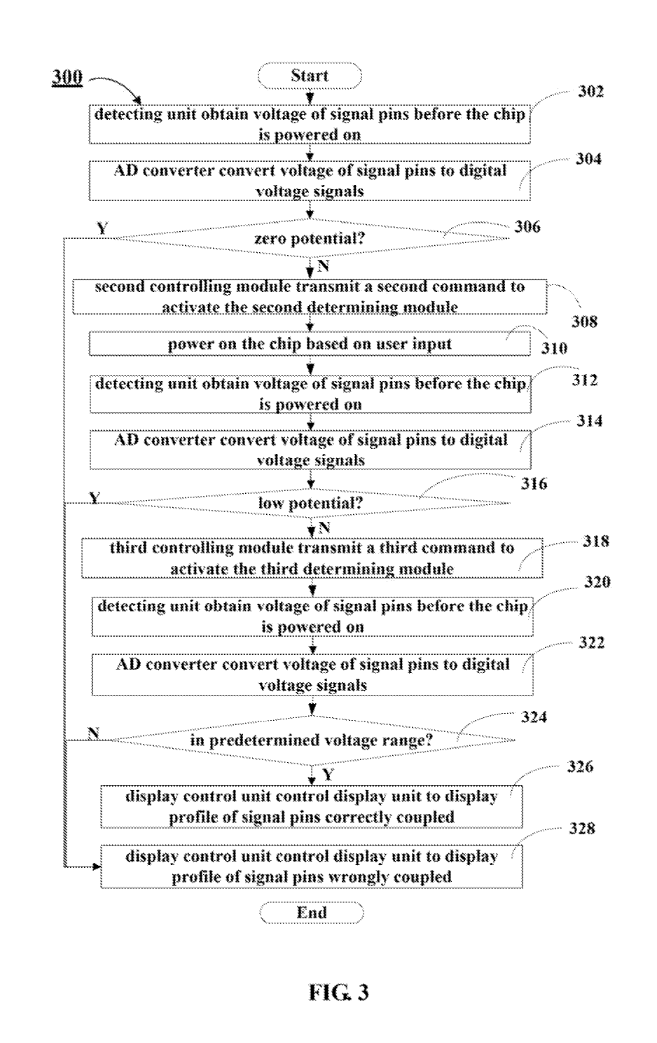

Referring to FIG. 3, a flowchart is presented in accordance with an example embodiment which is being thus illustrated. The example method 300 is provided by way of example, as there are a variety of ways to carry out the method. The method 300 described below can be carried out using the configurations illustrated in FIGS. 1˜2, for example, and various elements of these figures are referenced in explaining example method 300. Each block shown in FIG. 3 represents one or more processes, methods or subroutines, carried out in the exemplary method 300. Additionally, the illustrated order of blocks is by example only and the order of the blocks can change according to the present disclosure. The exemplary method 300 for detecting a chip of an electronic device can be executed at a detection device and begin at block 302.

At block 302, a detecting unit of the detection device obtains voltage of signal pins of the chip before the chip is powered on. In the exemplary embodiment, the number of the signal pins of the chip is 4.

At block 304, an AD converter of the detection device converts the obtained voltage to digital voltage signals.

At block 306, a first determining module of the detection device determines whether the digital voltage signals are zero potential. If the digital voltage signals are zero potential, the process goes to block 320, otherwise, the process goes to block 308.

At block 308, a second controlling module of the detection device transmits a second command to activate a second determining module.

At block 310, the detection device powers on the chip based on a user input. In at least one embodiment, a first controlling module transmits a first command to activate the second determining module after the chip is powered on.

At block 312, the detecting unit the detection device obtains voltage of signal pins of the chip after the chip is powered on.

At block 314, the AD converter of the detection device converts the obtained voltage to digital voltage signals.

At block 316, the second determining module determines whether the digital voltage signals are low potential. If the digital voltage signals are low potential, the process goes to block 328, otherwise, the process goes to block 318.

At block 318, the third controlling module transmits a third command to activate the third determining module.

At block 320, the detecting unit the detection device obtains voltage of signal pins of the chip after the chip is powered on.

At block 322, the AD converter of the detection device converts the obtained voltage to digital voltage signals.

At block 324, the third determining module determines whether the digital voltage signals are in a predetermined voltage range in which the chip is correctly operational. If the digital voltage are in the predetermined voltage range, the process goes to block 326, otherwise, the process goes to block 328.

At block 326, the display control unit controls the display unit to display a profile of the signal pins correctly coupled.

At block 328, the display control unit controls the display unit to display a profile of the signal pins wrongly coupled. In detail, if the digital voltage signals are zero potential before the chip is powered on, the signal pins are proved to be wrongly coupled to the ground. If the digital voltage signals are low potential after the chip is powered on, the signal pins are proved to be wrongly coupled to an open circuit. In at least one embodiment, if the signal pins are proved to be wrongly coupled, the method 300 can include a block at which a warning message can be issued via a warning unit, for example, a speaker, or a LED.

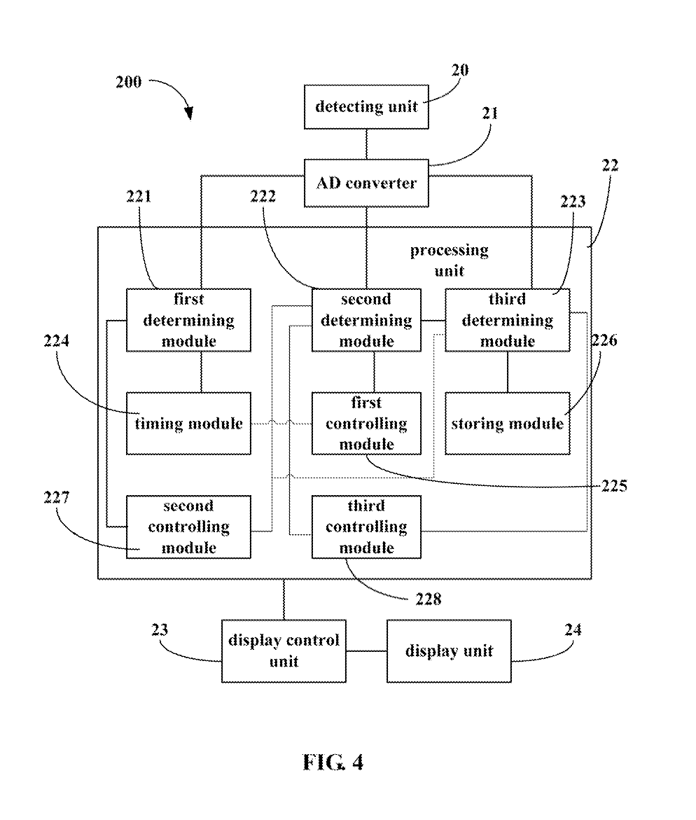

Referring to FIG. 4, a diagrammatic view of a second exemplary embodiment of a detection device 200 is illustrated. In the exemplary embodiment, the detection device 200 can has a similar structure with the detection device 100. The detection device 200 can be a microprocessor, a field-programmable gate array (FPGA), or a complicated programmable logic device (CPLD). The detection device 200 can include a detecting unit 20, an analog-digital (AD) converter 21, a processing unit 22, a display control unit 23, and a display unit 24 coupled in turn.

Similar to the detecting unit 10, the detecting unit 20 can include a first detecting circuit 201 and a second detecting circuit 202. The first detecting circuit 201 can have two connecting points, for example, a3 and a4, coupled to two signal pins, for example, 16a and 16b of the chip respectively. In the exemplary embodiment, the chip can have four signal pins 16a˜16d. Accordingly, the detecting unit 20 can include two detecting circuit 201, 201 corresponding to the signal pins 16a˜16d. In at least one embodiment, the number of the chip can have more or less than four signal pins, and the detecting unit 20 can have more or less than two detecting circuits accordingly. The first detecting circuit 201 can have same structure with the second detecting circuit 202.

Similar to the AD converter 11, the AD converter 21 can include a plurality of converting units coupled to the signal pins of the chip respectively. In the exemplary embodiment, the chip can have four signal pins 16a˜16d, and the AD converter 21 can include four converting units 211˜214 coupled to the four signal pins 16a˜16d respectively. The four converting units 211˜214 can be configured to convert the voltage of the signal pins to digital voltage signals.

One end of the first detecting circuit 201 can be coupled to VCC, and the other end of the first detecting circuit 201 can be coupled to AD converter 21. The first detecting circuit 201 can include a diode D2 having an anode coupled to VCC and a cathode coupled to the ground via resistive element, for example, R5 and R6. The AD converter 21 can be coupled to a first connection point a3 between the two resistive elements R5 and R6. The first connection point a3 can be coupled to the ground via resistive elements R7 and R8. A second connection point a4 between the resistive elements R7 and R8 can be coupled to the AD converter 21. The first and second connection points a3 and a4 can be coupled to signal pins 16a, 16b respectively.

Similar to the processing unit 12, the processing unit 22 can include a first determining module 221, a second determining module 222, a third determining module 223, a first controlling module 224, a second controlling module 225, a third controlling module 226, and a storing module 227, and a timing module 228. The processing unit 22 is different than the processing unit 12 in that the processing unit 22 can include a timing module 228 coupled between the first determining module 221 and the first controlling module 225.

The first determining module 221 can be configured to determine whether the digital voltage signals are zero potential before the chip is powered on. The timing module 228 can be configured to begin timing if the digital voltage signals before the chip are not zero potential. The timing module 228 further can be configured to transmit a power on command to power on the chip 26. The first controlling module 224 can be configured to transmit a first command to activate the second determining module 222. The second controlling module 225 can be configured to transmit a second command to activate the second determining module 222 if the digital voltage signals before the chip are not zero potential. The second determining module 222 can be configured to determine whether the digital voltage signals are low potential after the chip is powered on. The third controlling module 223 can be configured to transmit a third command to activate the third determining module 223. The third determining module 223 can be configured to determine whether the digital voltage signals are within the predetermined voltage range after the chip is powered on. The predetermined voltage range can be stored in the storing module 227.

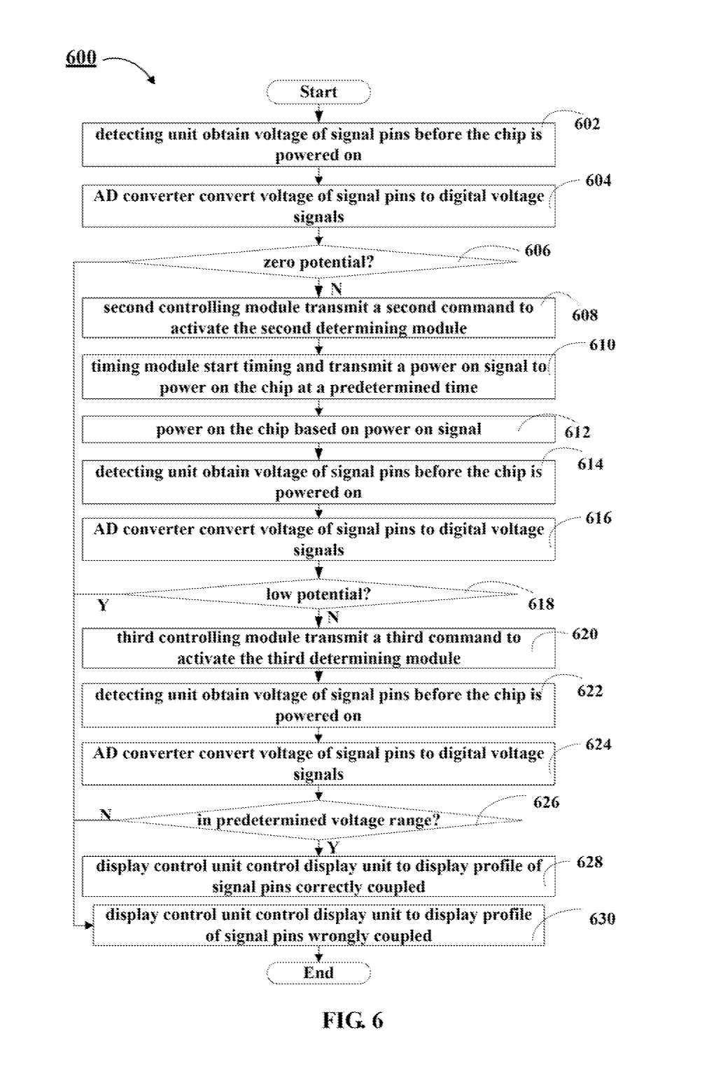

Referring to FIG. 6, a flowchart of a second exemplary embodiment of a detecting method is illustrated. The example method 600 is provided by way of example, as there are a variety of ways to carry out the method. The method 600 described below can be carried out using the configurations illustrated in FIGS. 4˜5, for example, and various elements of these figures are referenced in explaining example method 600. Each block shown in FIG. 6 represents one or more processes, methods or subroutines, carried out in the exemplary method 600. Additionally, the illustrated order of blocks is by example only and the order of the blocks can change according to the present disclosure. The exemplary method 600 for detecting a chip of an electronic device can be executed at a detection device and begin at block 602.

At block 602, a detecting unit of the detection device obtains voltage of signal pins of the chip before the chip is powered on.

At block 604, an AD converter of the detection device converts the obtained voltage to digital voltage signals.

At block 606, a first determining module of the detection device determines whether the digital voltage signals are zero potential. If the digital voltage signals are zero potential, the process goes to block 630, otherwise, the process goes to block 608.

At block 608, a second controlling module of the detection device transmits a second command to activate a second determining module.

At block 610, a timing module of the detection device begins timing and transmits a power on signal to power on the chip when the time reaches a predetermined time. In at least one embodiment, a first controlling module transmits a first command to activate the second determining module after the chip is powered on.

At block 612, the detection unit powered on the chip based on the power on signal.

At block 614, the detecting unit the detection device obtains voltage of signal pins of the chip after the chip is powered on.

At block 616, the AD converter of the detection device converts the obtained voltage to digital voltage signals.

At block 618, the second determining module determines whether the digital voltage signals are low potential. If the digital voltage signals are low potential, the process goes to block 630, otherwise, the process goes to block 620.

At block 620, the third controlling module transmits a third command to activate the third determining module.

At block 622, the detecting unit the detection device obtains voltage of signal pins of the chip after the chip is powered on.

At block 624, the AD converter of the detection device converts the obtained voltage to digital voltage signals.

At block 626, the third determining module determines whether the digital voltage signals are in a predetermined voltage range in which the chip is correctly operational. If the digital voltage signals are in the predetermined voltage range, the process goes to block 628, otherwise, the process goes to block 630.

At block 628, the display control unit controls the display unit to display a profile of the signal pins correctly coupled.

At block 630, the display control unit controls the display unit to display a profile of the signal pins wrongly coupled. In detail, if the digital voltage signals are zero potential before the chip is powered on, the signal pins are proved to be wrongly coupled to the ground. If the digital voltage signals are low potential after the chip is powered on, the signal pins are proved to be wrongly coupled to an open circuit. In at least one embodiment, if the signal pins are proved to be wrongly coupled, the method 600 can include a block at which a warning message can be issued via a warning unit, for example, a speaker, or a LED.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A detection method for an electronic device comprising:
obtaining, at a detection device, a voltage of at least one signal pin of a chip coupled to the detection device;
converting, at the detection device, the obtained voltage to one or more digital voltage signals; and
determining, at the detection device, if the one or more digital voltage signals are in a predetermined voltage range in which the chip is correctly operational.

2. The method according to claim 1, further comprising: displaying, at the detection device, a profile of the signal pins.

3. The method according to claim 1, further comprising:
obtaining, at the detection device, a voltage of the at least one signal pin of the chip before the chip is powered on;
converting, at the detection device, the obtained voltage to one or more digital voltage signals before the chip is powered on; and
determining, at the detection device, whether the one or more digital voltage signals before the chip is powered on are zero potential, wherein the at least one signal pin is incorrectly coupled to a ground if the one or more digital voltage signals before the chip is powered on are zero potential.

4. The method according to claim 1, further comprising:
obtaining, at the detection device, a voltage of the at least one signal pin of the chip after the chip is powered on;
converting, at the detection device, the obtained voltage to one or more digital voltage signals after the chip is powered on; and
determining, at the detection device, whether the one or more digital voltage signals after the chip is powered on are low potential, wherein the at least one signal pin is incorrectly coupled to an open circuit if the one or more digital voltage signals after the chip is powered on are low potential.

5. The method according to claim 4, further comprising: displaying, at the detection device, a profile of the signal pins incorrectly coupled.

6. The method according to claim 5, further comprising: issuing, at the detection device, a light or voice warning message if the signal pins are wrongly coupled.

7. The method according to claim 4, further comprising: powering on the chip based on user input or a timer.

8. A detection device for an electronic device having a chip, wherein the chip includes a plurality of signal pins, the device comprising:
a detecting unit coupled to the plurality of signal pins of the chip and configured to obtain a voltage of the plurality of signal pins;
an AD converter coupled to the detecting unit and configured to convert the obtained voltage of the signal pins to one or more digital voltage signals;
a processing unit coupled to the AD converter to determine whether the one or more digital voltage signals are in a predetermined voltage range in which the chip is correctly operational, wherein the signal pins are correctly coupled if the one or more digital voltage signals are in the predetermined voltage range.

9. The device according to claim 8, further comprising: a display unit configured to display a profile of the plurality of signal pins.

10. The device according to claim 8, further comprising an input unit configured to receive user input to power on the chip.

11. The device according to claim 8, wherein the processing unit comprises:
a first determining module configured to determine whether the digital voltage signals before the chip is powered on are zero potential;
a second determining module configured to determine whether the digital voltage signals after the chip is powered on are low potential; and
a third determining module configured to determine whether the digital voltage signals after the chip is within the predetermined voltage range.

12. The device according to claim 8, wherein the processing unit further comprises a first controlling module configured to activate the second determining module if the chip is powered on.

13. The device according to claim 8, wherein the processing unit further comprises a second controlling unit configured to activate the second determining module if the digital voltage signals are not zero potential before the chip is powered on.

14. The device according to claim 8, wherein the processing unit further comprises a third controlling module configured to activate the third determining module if the digital voltage signals are not low potential after the chip is powered on.

15. The device according to claim 8, wherein the processing unit further comprises a timing module configured to transmit a power on command to power on the chip at a predetermined time.
